(19) United States
(12) Patent Application Publication
(10) Pub. No.: US 2023/0238262 A1
(43) Pub. Date: Jul. 27, 2023

(54) SEMICONDUCTOR MANUFACTURING PROCESS PREDICTION METHOD AND SEMICONDUCTOR MANUFACTURING PROCESS PREDICTION DEVICE

(71) Applicant: UNITED MICROELECTRONICS CORP., Hsinchu (TW)

(72) Inventors: Hsiao-Ying YANG, Tainan City (TW); Ching-Pei LIN, Hsinchu County (TW); Chung-Yi CHIU, Tainan City (TW); Ming-Wei CHEN, Tainan City (TW); Te-Hsuan CHEN, Tainan City (TW); Chia-Wei CHEN, Chiayi City (TW); Wen-Shan HUANG, Kaohsiung City (TW)

(21) Appl. No.: 17/695,299

(22) Filed: Mar. 15, 2022

(30) Foreign Application Priority Data
Jan. 21, 2022 (CN) 202210071920.7

(51) Int. Cl. H01L 21/67; G06N 20/00

(52) U.S. Cl. CPC H01L 21/67276; G06N 20/00

(57) ABSTRACT

A semiconductor manufacturing process prediction method and a semiconductor manufacturing process prediction device are provided. The semiconductor manufacturing process prediction method includes the following steps. A plurality of process data are obtained. According to the process data, a machine learning model is used to execute prediction and obtain a prediction confidence and a prediction yield. Whether the prediction confidence is lower than a predetermined level is determined. If the prediction confidence is lower than the predetermined level, the machine learning model is modified. According to the process data, the prediction yield is adjusted.

This application claims the benefit of People's Republic of China application Serial No. 202210071920.7, filed Jan. 21, 2022, the disclosure of which is incorporated by reference herein in its entirety.

### TECHNICAL FIELD

The disclosure relates in general to a manufacturing process prediction method and a manufacturing process prediction, and more particularly to a semiconductor manufacturing process prediction method and a semiconductor manufacturing process prediction.

### BACKGROUND

With the high development of semiconductor technology, various complex semiconductor components are constantly being introduced. In the semiconductor manufacturing process, a wafer needs to go through thousands of processes to produce the final product. Therefore, researchers need to use appropriate prediction methods for the semiconductor process to predict the electrical function and yield of the final product, so as to avoid a large number of defective products in the final product.

### SUMMARY

The disclosure is directed to a semiconductor manufacturing process prediction method and a semiconductor manufacturing process prediction. A two-stage procedure used for prediction can not only modify the model, but also increase the flexibility of process prediction and greatly improve the prediction accuracy.

According to one embodiment, a semiconductor manufacturing process prediction method is provided. The semiconductor manufacturing process prediction method includes the following steps. A plurality of process data are obtained. A prediction is executed, according to the process data, via a machine learning model, to obtain a prediction confidence and a prediction yield. Whether the prediction confidence is lower than a predetermined level is determined. If the prediction confidence is lower than the predetermined level, the machine learning model is modified. The prediction yield is adjusted according to the process data.

According to another embodiment, a semiconductor manufacturing process prediction device is provided. The semiconductor manufacturing process prediction device includes a receiving unit, a prediction unit, a modifying unit and an adjustment unit. The receiving unit is configured to obtain a plurality of process data. The prediction unit is configured to execute, according to the process data, a prediction via a machine learning model, to obtain a prediction confidence and a prediction yield. The modifying unit is configured to determining whether the prediction confidence is lower than a predetermined level. If the prediction confidence is lower than the predetermined level, the modifying unit modifies the machine learning model. The adjustment unit is configured to adjust the prediction yield according to the process data.

### BRIEF DESCRIPTION OF THE DRAWINGS

FIG. 1 shows a schematic diagram of a semiconductor process according to an embodiment.

FIG. 2 shows a block diagram of a semiconductor manufacturing process prediction device according to an embodiment.

FIG. 3 shows a flowchart of a semiconductor manufacturing process prediction method according to an embodiment.

FIG. 4 illustrates a data flow for performing the semiconductor manufacturing process prediction method of FIG. 3 according to an embodiment.

FIG. 5 is a schematic diagram of the process data according to an embodiment.

FIG. 6 shows an example of the particle.

FIG. 7 shows an example of the scratch.

FIG. 8 shows an example of the crack.

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

### DETAILED DESCRIPTION

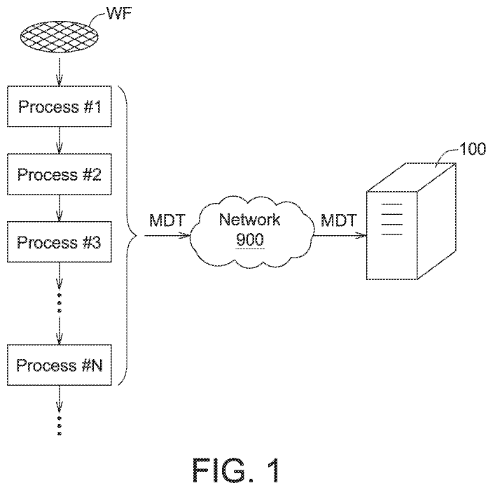

Please refer to FIG. 1, which shows a schematic diagram of a semiconductor process according to an embodiment. In the semiconductor manufacturing process, the wafer WF needs to go through thousands processes to produce the final product. During the manufacturing process, various process data MDTs can be collected and transmitted to the remote semiconductor manufacturing process prediction device 100 through the network 900 for yield prediction. The semiconductor manufacturing process prediction device 100 is, for example, a server, or a computing cluster. Once it is found that the yield may be too low, equipment inspection, equipment parameter adjustment, recipe, fixture adjustment, and vehicle adjustment can be performed immediately to avoid the occurrence of a large number of defective products.

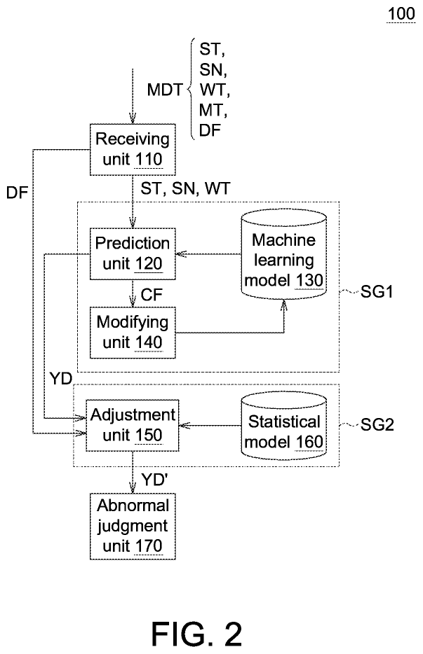

Please refer to FIG. 2, which shows a block diagram of a semiconductor manufacturing process prediction device 100 according to an embodiment. The semiconductor manufacturing process prediction device 100 includes a receiving unit 110, a prediction unit 120, a machine learning model 130, a modifying unit 140, an adjustment unit 150, a statistical model 160 and an abnormal judgment unit 170. The functions of the components are outlined below. The receiving unit 110 is used for receiving data, such as a wireless network transmission module, a wired network transmission module, a Bluetooth receiving module or an LTE transmission module. The prediction unit 120 is used to make predictions. The machine learning model 130 is an artificial intelligence model, such as a neural network model, a deep learning model or a classification calculus model. The modifying unit 140 is used to modify the machine learning model 130. The adjustment unit 150 is used to adjust the prediction results. The statistical model 160 is an adjustment mechanism based on historical records. The abnormal judgment unit 170 is used for abnormal judgment. The prediction unit 120, the machine learning model 130, the modifying unit 140, the adjustment unit 150, the statistical model 160 and/or the abnormal judgment unit is, for example, a circuit, a chip, a circuit board, a code or a storage medium for storing the code. In this embodiment, the semiconductor manufacturing process prediction device 100 adopts a two-stage procedure for prediction. In the first stage SG1, the semiconductor manufacturing process prediction device 100 uses the machine learning model 130 to make a preliminary prediction of the prediction yield YD, and uses a prediction confidence CF to confirm the accuracy of the machine learning model 130. Then, in the second stage SG2, the semiconductor manufacturing process prediction device 100 further adjusts and judges the prediction yield YD. The following is a flow chart to describe the operation of the above components in detail.

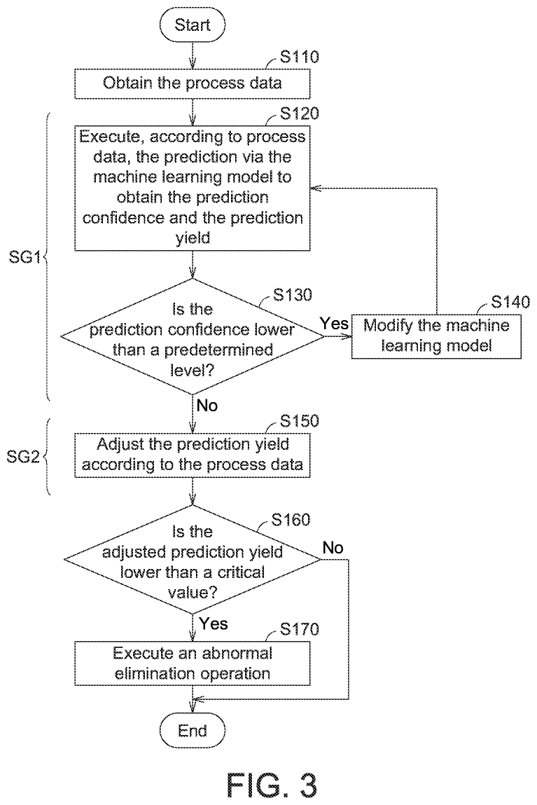

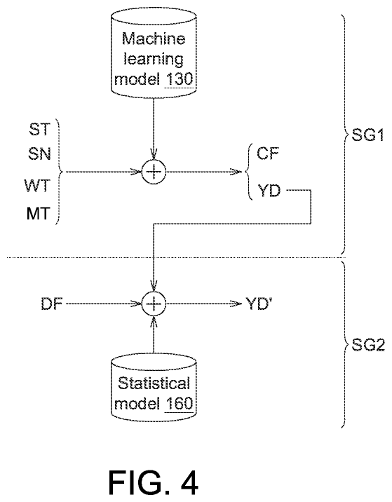

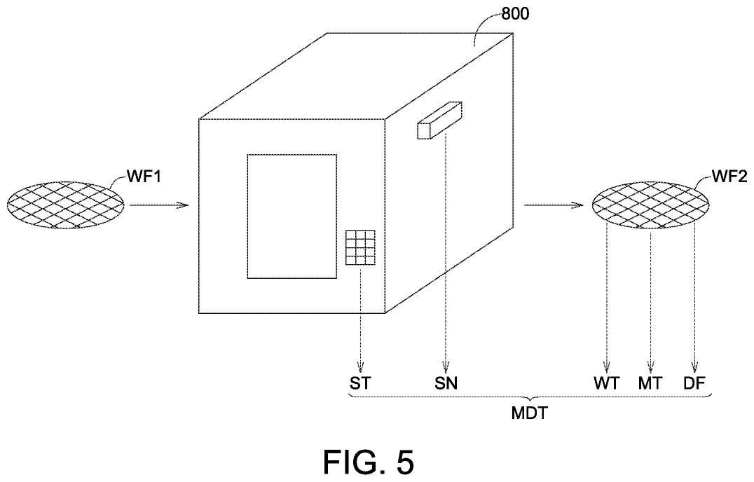

Please refer to FIG. 3 and FIG. 4. FIG. 3 shows a flowchart of a semiconductor manufacturing process prediction method according to an embodiment. FIG. 4 illustrates a data flow for performing the semiconductor manufacturing process prediction method of FIG. 3 according to an embodiment. The semiconductor manufacturing process prediction method of this embodiment can be executed after loading a computer program product through a computer. In step S110, the receiving unit 110 obtains the process data MDT. Please refer to FIG. 4 and FIG. 5. FIG. 5 is a schematic diagram of the process data MDT according to an embodiment. For example, the wafer WF1 has accumulated some process data MDT after one or more processes. The process data MDT includes at least one equipment setting data ST, at least one equipment detecting data SN, at least one electrical measurement data WT, at least one physical measurement data MT and at least one physical defect data DF. The equipment setting data ST is, for example, the temperature set in the equipment 800, the pressure set in the equipment 800, the processing time set in the equipment 800, the gas used in the equipment 800, the gas flow set in the equipment 800, and so on. The equipment detecting data SN is, for example, the temperature detected by the equipment 800, the pressure detected by the equipment 800, the wavelength of light measured by the equipment 800, and so on. The electrical measurement data WT is, for example, Wafer Acceptance Test (WAT), which is used to test the electrical parameters of NMOS, PMOS, resistance, contact resistance or internal connection on the wafer WF2. The physical measurement data MT is, for example, measurement data (metrology data), such as width and thickness, detected by an optical microscope, an electron microscope or an ion microscope. The physical defect data DF is, for example, particle, scratch, crack, etc. detected by the optical microscope, the electron microscope or the ion microscope.

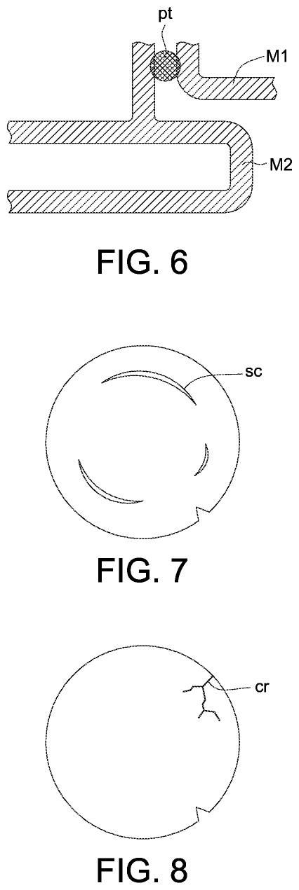

Please refer to FIG. 6, which shows an example of the particle pt. When the particle pt is located between two wires M1, M2, it will cause a short circuit. Therefore, the particle pt has a significant impact on yield. Please refer to FIG. 7, which shows an example of the scratch sc. The scratch sc may destroy the element structure. Therefore, the scratch sc has a significant impact on yield. Please refer to FIG. 8, which shows an example of the crack cr. The crack cr may damage the wiring or cause wafer breaking. Therefore, the crack cr also has a significant impact on yield.

Compared with the physical defect data DF, the equipment setting data ST, the equipment detecting data SN, the electrical measurement data WT and the physical measurement data MT have indirect and less obvious influence on yield, and can be called soft process data. The soft process data, such as the equipment setting data ST, the equipment detecting data SN, the electrical measurement data WT and the physical measurement data MT, are very suitable applied to the machine learning model 130 in the first stage SG1 to make a preliminary prediction of the prediction yield YD. The physical defect data DF has a very direct and obvious influence on yield, and can be called hard process data. The hard process data, such as the physical defect data DF, is suitable applied to statistical model 160 in the second stage SG2 to further adjust and judge the prediction yield YD.

The following continue to explain the steps S120 to S140 of the first stage SG1 and the step S150 of the second stage SG2.

In step S120 of the first stage SG1, the prediction unit 120 executes, according to process data MDT, the prediction via the machine learning model 130 to obtain the prediction confidence CF and the prediction yield YD. As shown in FIG. 4, only the soft process data, such as the equipment setting data ST, the equipment detecting data SN, the electrical measurement data WT and the physical measurement data MT, are used for prediction in this step. The hard process data, such as the physical defect data DF, is not considered in this step.

Then, in step S130 of the first stage SG1, the modifying unit 140 determines whether the prediction confidence CF is lower than a predetermined level. If the prediction confidence CF is lower than the predetermined level, the process proceeds to step S140; if the prediction confidence CF is not lower than the predetermined level, the process proceeds to step S150. The prediction confidence CF represents the accuracy of the machine learning model 130. If the prediction confidence CF is too low, it means that the machine learning model 130 needs to be modified or even replaced.

Then, in the step S140 of the first stage SG1, the modifying unit 140 modifies the machine learning model 130. In this step, the modifying unit 140 can modify the parameters or weights of the machine learning model 130 and then perform training. Alternatively, the modifying unit 140 can modify the training dataset of the machine learning model 130 and then perform training. Or, the modifying unit 140 can replace the machine learning model 130. After the machine learning model 130 is modified, the step S120 and the step S130 of the first stage SG1 are repeatedly executed until the prediction confidence CF reaches the predetermined level.

In above-mentioned first stage SG1, the hard process data, such as the physical defect data DF, is not considered. Generally speaking, the physical defect data DF is an accidental event, not a normal event in the process. Therefore, excluding the use of the physical defect data DF in the first stage SG1 can ensure that the prediction confidence CF and the prediction yield YD obtained by the machine learning model 130 are not deviated by the accidental events. Once the prediction confidence CF of the machine learning model 130 can reach the predetermined level, it can be sure that the prediction yield YD obtained by the machine learning model 130 has a certain accuracy.

Then, the process proceeds to the step S150 of the second stage SG2. In step S150, the adjustment unit 150 adjusts the prediction yield YD according to the process data MDT. In this step, the adjustment unit 150 adjusts the prediction yield YD to be a prediction yield YD′ via the statistical model 160 according to the physical defect data DF. The statistical model 160 is different from the machine learning model 130. The statistical model 160 is an adjustment procedure based on historical records. For example, the statistical model 160 gives corresponding different deduction degrees for the particle pt, the scratch cr and the crack sc. The adjusted prediction yield YD′ can reflect accidental events, such as the physical defect data DF.

Then, in step S160, the abnormal judgment unit 170 determines whether the adjusted prediction yield YD′ is lower than a critical value. If the prediction yield YD′ is lower than the critical value, the process proceeds to step S170.

In step S170, an abnormal elimination operation is executed. The abnormal elimination operation, such as equipment inspection, equipment parameter adjustment, recipe adjustment, fixture adjustment, or vehicle adjustment, is executed to avoid the occurrence of a large number of defective products.

Referring to FIG. 4, in the first stage SG1, the prediction is mainly executed according to the soft process data, such as the equipment setting data ST, the equipment detecting data SN, the electrical measurement data WT and the physical measurement data MT, to obtain the prediction confidence CF and the prediction yield YD. The machine learning model 130 can continue to modify itself until the prediction confidence CF reaches the predetermined level. Once the prediction confidence CF of the machine learning model 130 reaches the predetermined level, it can be sure that the prediction yield YD obtained by the machine learning model 130 has a certain accuracy.

In the first stage SG1, the hard process data, such as the physical defect data DF, is not considered. Excluding the physical defect data DF in the first stage SG1 can ensure that the prediction confidence CF and the prediction yield YD obtained by the machine learning model 130 are not biased by the accidental events.

In the second stage SG2, the hard process data, such as the physical defect data DF, is considered for adjusting the prediction yield YD to be the prediction yield YD′. The adjusted prediction yield YD′ can reflect the accidental events, such as the physical defect data DF.

Since any accidental events, such as the physical defect data DF, can be considered in the second stage SG2, the process prediction is more flexible. The prediction yield YD can be adjusted immediately once any accidental event is found, without the need to spend time and resources re-executing (or training) the machine learning model 130.

When predicting through the above-mentioned two-stage procedure, the prediction accuracy of the machine learning model 130 for the normal events can be ensured, and the impact of accidental events on the yield will not be missed, so that the prediction accuracy can be greatly improved and more steady.

It will be apparent to those skilled in the art that various modifications and variations can be made to the disclosed embodiments. It is intended that the specification and examples be considered as exemplary only, with a true scope of the disclosure being indicated by the following claims and their equivalents.

What is claimed is:

1. A semiconductor manufacturing process prediction method, comprising:
obtaining a plurality of process data;
executing, according to the process data, a prediction via a machine learning model, to obtain a prediction confidence and a prediction yield;
determining whether the prediction confidence is lower than a predetermined level;
modifying the machine learning model, if the prediction confidence is lower than the predetermined level; and
adjusting the prediction yield according to the process data.

2. The semiconductor manufacturing process prediction method according to claim 1, wherein in the step of modifying the machine learning model, a parameter or a weight of the machine learning model is modified.

3. The semiconductor manufacturing process prediction method according to claim 1, wherein the in the step of modifying the machine learning model, a training dataset of the machine learning model is modified.

4. The semiconductor manufacturing process prediction method according to claim 1, wherein the process data includes at least one equipment setting data, at least one equipment detecting data, at least one electrical measurement data, at least one physical measurement data and at least one physical defect data, in the step of executing the prediction, the prediction is executed according to the equipment setting data, the equipment detecting data, the electrical measurement data and the physical measurement data.

5. The semiconductor manufacturing process prediction method according to claim 1, wherein the process data includes at least one equipment setting data, at least one equipment detecting data, at least one electrical measurement data, at least one physical measurement data and at least one physical defect data, in the step of adjusting the prediction yield, the prediction yield is adjusted according to the physical defect data.

6. The semiconductor manufacturing process prediction method according to claim 5, wherein the prediction yield is adjusted via a statistical model, and the statistical model is different from the machine learning model.

7. A semiconductor manufacturing process prediction device, comprising:
a receiving unit, configured to obtain a plurality of process data;
a prediction unit, configured to execute, according to the process data, a prediction via a machine learning model, to obtain a prediction confidence and a prediction yield;
a modifying unit, configured to determining whether the prediction confidence is lower than a predetermined level, wherein if the prediction confidence is lower than the predetermined level, the modifying unit modifies the machine learning model; and
an adjustment unit, configured to adjust the prediction yield according to the process data.

8. The semiconductor manufacturing process prediction device according to claim 7, wherein the modifying unit modifies a parameter or a weight of the machine learning model.

9. The semiconductor manufacturing process prediction device according to claim 7, wherein the modifying unit modifies a training dataset of the machine learning model.

10. The semiconductor manufacturing process prediction device according to claim 7, wherein the process data includes at least one equipment setting data, at least one equipment detecting data, at least one electrical measurement data, at least one physical measurement data and at least one physical defect data, and the prediction unit executes the prediction according to the equipment setting data, the equipment detecting data, the electrical measurement data and the physical measurement data.

11. The semiconductor manufacturing process prediction device according to claim 7, wherein the process data includes at least one equipment setting data, at least one equipment detecting data, at least one electrical measurement data, at least one physical measurement data and at least one physical defect data, and the adjustment unit adjusts the prediction yield according to the physical defect data.

12. The semiconductor manufacturing process prediction device according to claim 11, wherein the adjustment unit adjusts the prediction yield via a statistical model, and the statistical model is different from the machine learning model.
